(19) United States
(12) Patent Application Publication
(10) Pub. No.: US 2022/0121104 A1
(43) Pub. Date: Apr. 21, 2022

(54) MASK BLANK, PHASE SHIFT MASK, AND METHOD FOR MANUFACTURING SEMICONDUCTOR DEVICE

(71) Applicant: HOYA CORPORATION, Tokyo (JP)

(72) Inventors: Hitoshi MAEDA, Tokyo (JP); Osamu NOZAWA, Tokyo (JP)

(73) Assignee: HOYA CORPORATION, Tokyo (JP)

(21) Appl. No.: 17/298,248

(22) PCT Filed: Dec. 10, 2019
(86) PCT No.: PCT/JP2019/048263

§ 371 Date: May 28, 2021

(30) Foreign Application Priority Data
Dec. 25, 2018 (JP) 2018-240971

(51) Int. Cl. G03F 1/32

(52) U.S. Cl. CPC G03F 1/32

(57) ABSTRACT

Provided is a mask blank, including a phase shift film.

The phase shift film has a function to transmit an exposure light of an ArF excimer laser at a transmittance of 15% or more and a function to generate a phase difference of 150 degrees or more and 210 degrees or less; the phase shift film is formed of a material containing a non-metallic element and silicon; the phase shift film has a structure where a first layer, a second layer, and a third layer are stacked in this order; refractive indexes n₁, n₂, n₃ of the first, second, and third layers, respectively, at a wavelength of an exposure light satisfy relations of n₁>n₂ and n₂<n₃; extinction coefficients k₁, k₂, k₃ of the first, second, and third layers, respectively, at a wavelength of an exposure light satisfy relations of k₁>k₂ and k₂<k₃; and film thicknesses di, d₃ of the first layer and the third layer, respectively, satisfy a relation of 0.5≤d₁/d₃<1.

### CROSS-REFERENCE TO RELATED APPLICATIONS

This application is the National Stage of International Application No. PCT/JP2019/048263, filed Dec. 10, 2021, which claims priority to Japanese Patent Application No. 2018-240971, filed Dec. 25, 2018, and the contents of which is incorporated by reference.

### TECHNICAL FIELD

This disclosure relates to a mask blank and a phase shift mask manufactured using the mask blank. This disclosure further relates to a method of manufacturing a semiconductor device using the phase shift mask.

### BACKGROUND ART

Generally, in a manufacturing process of a semiconductor device, photolithography is used to form a fine pattern. Multiple substrates called transfer masks are usually utilized in forming the fine pattern. In order to miniaturize a pattern of a semiconductor device, in addition to miniaturization of a mask pattern formed on a transfer mask, it is necessary to shorten a wavelength of an exposure light source used in photolithography. Shortening of wavelength has been advancing recently from the use of KrF excimer laser (wavelength 248 nm) to ArF excimer laser (wavelength 193 nm) as an exposure light source in the manufacture of a semiconductor device.

As for the types of transfer masks, a half tone phase shift mask is known in addition to a conventional binary mask having a light shielding pattern made of a chromium-based material on a transparent substrate. A molybdenum silicide (MoSi)-based material is widely used for a phase shift film of a half tone phase shift mask.

In recent years, studies have been conducted to apply Si-based materials such as SiN and SiON having high ArF light fastness to phase shift films. Si-based materials tend to have low light shielding properties compared to MoSi-based materials, and it was relatively difficult to apply these materials to phase shift films having a transmittance of less than 10% that are conventionally widely used. On the contrary, Si-based materials can be applied easily to phase shift films having relatively high transmittance of 10% or more (Patent Document 1).

On the other hand, when a phase shift mask of a half tone phase shift mask was set on an exposure apparatus and irradiated with an ArF exposure light, there was a problem of position displacement of a pattern of the phase shift film. The problem is caused by an ArF exposure light absorbed within a pattern of the phase shift film transforming into thermal energy, and the heat is transmitted to the transparent substrate to cause thermal expansion (Patent Document 2).

### PRIOR ART PUBLICATIONS

### Patent Documents

### [Patent Document 1]

### Japanese Patent Application Publication 2015-111246

### [Patent Document 2]

### Japanese Patent Application Publication 2015-152924

### SUMMARY OF THE DISCLOSURE

### Problems to be Solved by the Disclosure

A phase shift film of a half tone phase shift mask (hereafter simply referred to as phase shift mask) should have a function to transmit an exposure light at a predetermined transmittance and also a function to generate a predetermined phase difference between the exposure light transmitted through the phase shift film and the exposure light transmitted through the air for a same distance as a thickness of the phase shift film. Recently, further miniaturization of semiconductor devices is in progress, and application of exposure technologies such as multiple patterning techniques is under way. There is increasing demand for overlay accuracy of each transfer mask of a set of transfer masks used in manufacturing one semiconductor device. Therefore, in the case of a phase shift mask as well, there is an increasing demand for preventing thermal expansion of a phase shift film pattern (phase shift pattern) to prevent displacement of the phase shift pattern caused thereby.

In Patent Document 2, a back surface reflectance of a thin film pattern when a photomask is set on an exposure apparatus and irradiated with an exposure light from a transparent substrate side (reflectance of the transparent substrate side) is set to be higher than conventional cases. An attempt to reduce heat generated by transformation of light energy of an exposure light absorbed by a thin film is made, by setting a back surface reflectance higher than conventional cases and suppressing occurrence of position displacement of the thin film pattern associated with thermal expansion of the transparent substrate. Proposed in Patent Document 2 as a mask blank for manufacturing a binary mask is a structure where a highly reflective material layer and a light shielding layer are stacked in this order on a transparent substrate. Further proposed as a mask blank for manufacturing a phase shift mask is a structure where a highly reflective material layer and a phase shifting layer are stacked in this order on a transparent substrate.

In the case of a mask blank for manufacturing a binary mask, the stacked structure of the highly reflective material layer and the light shielding layer requires predetermined light shielding properties. This is not difficult. On the other hand, in the case of a mask blank for manufacturing a phase shift mask, in addition to the stacked structure of the highly reflective material layer and the phase shifting layer having a function to transmit an exposure light at a predetermined transmittance, it is also required to have a function to generate a predetermined phase difference between the transmitting exposure light and the exposure light transmitted through the air for a same distance as a thickness of the stacked structure. Feasible variation is limited in a phase shift film with a design concept to ensure a predetermined back surface reflectance with a highly reflective material layer alone. Particularly, in the case of a study of a phase shift film with a relatively high transmittance (e.g., 15% or more) under the design concept relying on a highly reflective material layer, reduction of a back surface reflectance is inevitable when a predetermined transmittance and a predetermined phase difference are to be applied to the stacked structure of the highly reflective material layer and the phase shifting layer, causing difficulty in suppressing position displacement of the phase shift pattern.

This disclosure was made to solve the conventional problem. The aspect of the disclosure is to provide a mask blank having a phase shift film on a transparent substrate, the phase shift film having a function to transmit an ArF exposure light at a predetermined transmittance and also a function to generate a predetermined phase difference to the transmitting ArF exposure light, the phase shift film suppressing thermal expansion of the phase shift film pattern (phase shift pattern), and which can suppress displacement of the phase shift pattern caused thereby. A further aspect is to provide a phase shift mask manufactured using this mask blank. Yet another aspect of this disclosure is to provide a method of manufacturing a semiconductor device using such a phase shift mask.

### Means for Solving the Problem

For solving the above problem, this disclosure includes the following configurations.

### (Configuration 1)

A mask blank including a phase shift film on a transparent substrate,

in which the phase shift film has a function to transmit an exposure light of an ArF excimer laser at a transmittance of 15% or more, and a function to generate a phase difference of 150 degrees or more and 210 degrees or less between the exposure light transmitted through the phase shift film and the exposure light transmitted through the air for a same distance as a thickness of the phase shift film,

in which the phase shift film is formed of a material containing a non-metallic element and silicon,

in which the phase shift film has a structure where a first layer, a second layer, and a third layer are stacked in this order from a side of the transparent substrate,

in which refractive indexes n₁, n₂, and n₃ of the first layer, the second layer, and the third layer, respectively, at a wavelength of the exposure light satisfy relations of n₁>n₂ and n₂<n₃,

in which extinction coefficients k₁, k₂, and k₃ of the first layer, the second layer, and the third layer, respectively, at a wavelength of the exposure light satisfy relations of k₁>k₂ and k₂<k₃, and

in which film thicknesses d₁ and d₃ of the first layer and the third layer, respectively, satisfy a relation of 0.5≤d₁/d₃<1.

### (Configuration 2)

The mask blank according to Configuration 1, in which a film thickness d₂ of the second layer and a total film thickness d_{T} of three layers including the first layer, the second layer, and the third layer satisfy a relation of 0.24←₂/d_{T}≤0.3.

### (Configuration 3)

The mask blank according to Configuration 1 or 2, in which the first layer has the refractive index n₁ of 2.3 or more, and the extinction coefficient k₁ of 0.2 or more.

### (Configuration 4)

The mask blank according to any of Configurations 1 to 3, in which the second layer has the refractive index n₂ of 1.7 or more and the extinction coefficient k₂ of 0.01 or more.

### (Configuration 5)

The mask blank according to any of Configurations 1 to 4, in which the third layer has the refractive index n₃ of 2.3 or more and the extinction coefficient k₃ of 0.2 or more.

### (Configuration 6)

The mask blank according to any of Configurations 1 to 5, in which the phase shift film is formed of a material consisting of a non-metallic element and silicon, or a material consisting of a metalloid element, a non-metallic element, and silicon.

### (Configuration 7)

The mask blank according to any of Configurations 1 to 6, in which the first layer, the second layer, and the third layer are all formed of a material containing nitrogen.

### (Configuration 8)

The mask blank according to any of Configurations 1 to 7, in which the second layer is formed of a material containing oxygen.

### (Configuration 9)

The mask blank according to any of Configurations 1 to 8 including a light shielding film on the phase shift film.

### (Configuration 10)

A mask blank including a phase shift film having a transfer pattern on a transparent substrate,

in a transmittance of the phase shift film with respect to an exposure light of an ArF excimer laser at is 15% or more, and

in the phase shift film is configured to transmit the exposure light so that transmitted light has a phase difference of 150 degrees or more and 210 degrees or less with respect to the exposure light transmitted through the air for a same distance as a thickness of the phase shift film,

in which the phase shift film contains a non-metallic element and silicon,

in which the phase shift film has a structure where a first layer, a second layer, and a third layer are stacked in this order from a side of the transparent substrate,

in which refractive indexes n₁, n₂, and n₃ of the first layer, the second layer, and the third layer, respectively, at a wavelength of the exposure light satisfy relations of n₁>n₂ and n₂<n₃,

in which extinction coefficients k₁, k₂, and k₃ of the first layer, the second layer, and the third layer, respectively, at a wavelength of the exposure light satisfy relations of k₁>k₂ and k₂<k₃, and

in which film thicknesses d₁ and d₃ of the first layer and the third layer, respectively, satisfy a relation of 0.5≤d₁/d₃<1.

### (Configuration 11)

The phase shift mask according to Configuration 10, in which a film thickness d₂ of the second layer and a total film thickness d_{T} of three layers including the first layer, the second layer, and the third layer satisfy a relation of 0.24←₂/d_{T}≤0.3.

### (Configuration 12)

The phase shift mask according to Configuration 10 or 11, in which the first layer has the refractive index n₁ of 2.3 or more and the extinction coefficient k₁ of 0.2 or more.

### (Configuration 13)

The phase shift mask according to any of Configurations 10 to 12, in which the second layer has the refractive index n₂ of 1.7 or more and the extinction coefficient k₂ of 0.01 or more.

### (Configuration 14)

The phase shift mask according to any of Configurations 10 to 13, in which the third layer has the refractive index n₃ of 2.3 or more and the extinction coefficient k₃ of 0.2 or more.

### (Configuration 15)

The phase shift mask according to any of Configurations 10 to 14, in which the phase shift film is formed of a material consisting of a non-metallic element and silicon, or a material consisting of a metalloid element, a non-metallic element, and silicon.

### (Configuration 16)

The phase shift mask according to any of Configurations 10 to 15, in which the first layer, the second layer, and the third layer are all formed of a material containing nitrogen.

### (Configuration 17)

The phase shift mask according to any of Configurations 10 to 16, in which the second layer is formed of a material containing oxygen.

### (Configuration 18)

The phase shift mask according to any of Configurations 10 to 17 including a light shielding film having a pattern including a light shielding band on the phase shift film.

### (Configuration 19)

A method of manufacturing a phase shift mask using the mask blank according to Configuration 9, including the steps of:

forming a transfer pattern in the light shielding film by dry etching;

forming a transfer pattern in the phase shift film by dry etching with the light shielding film having the transfer pattern as a mask; and

forming a pattern including a light shielding band in the light shielding film by dry etching with a resist film having a pattern including a light shielding band as a mask.

### (Configuration 20)

A method of manufacturing a semiconductor device including the step of using the phase shift mask according to Configuration 18 and subjecting a resist film on a semiconductor substrate to exposure transfer of a transfer pattern.

### Effect of the Disclosure

The mask blank of this disclosure includes a phase shift film on a transparent substrate, the phase shift film having a function of transmitting an ArF exposure light at a predetermined transmittance and also a function of generating a predetermined phase difference to the transmitting ArF exposure light, the phase shift film suppressing thermal expansion of the phase shift film pattern (phase shift pattern) and can suppress displacement of the phase shift pattern caused thereby.

### BRIEF DESCRIPTION OF THE DRAWINGS

FIG. 1 is a cross-sectional view showing a configuration of the mask blank of the first embodiment of this disclosure.

FIG. 2 is a schematic cross-sectional view showing a manufacturing process of the phase shift mask of the first embodiment of this disclosure.

FIG. 3 is a graph showing a relation of a ratio (d₁/d₃) of a film thickness of the first layer to a film thickness of the third layer and an absorptivity A of the phase shift film.

FIG. 4 is a graph showing a relation of a ratio (d₂/d_{T}) of a film thickness of the second layer to a total film thickness and an absorptivity A of the phase shift film.

### EMBODIMENTS FOR CARRYING OUT THE DISCLOSURE

The embodiments of this disclosure are explained below. The inventors of this application diligently studied a phase shift film regarding means that can suppress position displacement of a pattern associated with thermal expansion, while having both of a function for transmitting an ArF exposure light at a predetermined transmittance and a function for generating a predetermined phase difference.

To suppress position displacement of a pattern associated with thermal expansion, it will be necessary to suppress an ArF exposure light from being transformed into thermal energy within a phase shift film. The inventors of this application obtained knowledge that temperature elevation of a phase shift film is approximately proportional to a square of a ratio of an ArF exposure light absorbed within a phase shift film (absorptivity A of ArF exposure light). Based on this knowledge, the inventors found that reducing an absorptivity A of an ArF exposure light down to 60% or less when the ArF exposure light entered into a transparent substrate is 100% is important for suppressing the transformation into thermal energy within the phase shift film mentioned above within a tolerable range. An absorptivity A, a transmittance T, and a back surface reflectance R (this back surface reflectance R refers to a back surface reflectance when an amount of ArF exposure light entering the transparent substrate from an interface of the air and the transparent substrate is 100%) of a phase shift film satisfy a relation of “A[%]=100[%]-(transmittance T[%]+back surface reflectance R[%])”. Therefore, to satisfy a predetermined transmittance T and an absorptivity A of 60% or less, it will be important to increase a back surface reflectance R to a certain extent.

To increase a back surface reflectance R of a phase shift film provided on a transparent substrate, it is necessary to form at least a layer of the phase shift film in contact with the transparent substrate from a material having a high extinction coefficient k at an exposure light wavelength. Due to the necessity to fulfill desired optical properties and film thickness, a phase shift film of a single layer structure is commonly formed of a material with a high refractive index n and a low extinction coefficient k. Consideration is made herein on increasing a back surface reflectance R of a phase shift film by adjusting the composition of a material forming the phase shift film and significantly increasing an extinction coefficient k. Since the adjustment precludes the phase shift film from satisfying the condition of a transmittance T of a predetermined range, it will be necessary to significantly reduce a thickness of the phase shift film. However, reduction of a thickness of the phase shift film will preclude the phase shift film from satisfying the condition of the phase difference of a predetermined range. Since there is a limitation in increasing a refractive index n of a material forming a phase shift film, it is difficult to increase a back surface reflectance R with a phase shift film of a single layer structure. In the case of a phase shift film with a relatively high transmittance T of 15% or more, it is particularly difficult to increase a back surface reflectance R with a phase shift film of a single layer structure.

On the other hand, in the case of a phase shift film of a two layer structure, while an adjustment is possible to increase a back surface reflectance R while satisfying the conditions of a transmittance T of a predetermined range and a phase difference of a predetermined range, design freedom is not as high. Particularly in the case of applying a two layer structure to achieve a phase shift film having optical properties of a predetermined phase difference (150 degrees or more and 210 degrees or less) and 15% or more transmittance that are enough to obtain a sufficient phase shifting effect, it is difficult to increase a back surface reflectance R and it is difficult to set an absorptivity A to 60% or less. The inventors diligently studied the possibility of simultaneously satisfying the above conditions in the case of a phase shift film consisting of a silicon-based material (material containing non-metallic element and silicon) and having a stacked structure of three or more layers. In the case of a phase shift film with a stacked structure of three or more layers as mentioned above, not only is an adjustment possible to increase a back surface reflectance R while satisfying the conditions of a transmittance T of a predetermined range and a phase difference of a predetermined range, but design freedom is high as well.

As a result, the inventors discovered that a phase shift film having a structure where a first layer, a second layer, and a third layer are stacked in this order with a refractive index n and an extinction coefficient k of each of the three layers satisfying predetermined relations can simultaneously fulfill the above conditions. Concretely, the inventors discovered that a phase shift film simultaneously satisfying the three conditions of a predetermined phase difference (150 degrees or more and 210 degrees or less), 15% or more transmittance T, and 60% or more absorptivity A can be achieved by a phase shift film where refractive indexes n₁, n₂, and n₃ of first, second, and third layers, respectively, at a wavelength of an ArF exposure light satisfy relations of n₁>n₂ and n₂<n₃, and extinction coefficients k₁, k₂, and k₃ of first, second, and third layers, respectively, at a wavelength of an ArF exposure light satisfy relations of k₁>k₂ and k₂<k₃.

The inventors of this application carried out an optical simulation of a phase shift film, focusing on a relation of a ratio of a film thickness d₁ of a first layer and a film thickness d₃ of a third layer (i.e., film thickness ratio d₁/d₃ which is a ratio of a film thickness d₁ of the first layer to a film thickness d₃ of the third layer) with an absorptivity A of the phase shift film. Concretely, a refractive index n and an extinction coefficient k of each of a first layer, a second layer, and a third layer of the phase shift film were initially set to values satisfying the predetermined relations given above. Next, film thicknesses d₁, d₂, and d₃ of the first layer, the second layer, and the third layer, respectively, were adjusted and a phase shift film was designed having desired transmittance and phase difference. Further, an optical simulation was carried out with parameters of the designed phase shift film, and an absorptivity A of the designed phase shift film having a film thickness ratio d₁/d₃ was calculated. The value of an absorptivity A was calculated using the aforementioned relational equation A[%]=100 [%]−(transmittance T[%]+back surface reflectance R[%]). Subsequently, film thicknesses d₁, d₃ of the first layer and the third layer of the designed phase shift film were increased/decreased, and phase shift films each having a film thickness ratio of d₁/d₃ were designed. Moreover, similar optical simulation was carried out, and an absorptivity A of the phase shift films at each film thickness ratio d₁/d₃ was calculated. There was a case where a transmittance and a phase difference of the phase shift film deviate relatively significantly from a desired value by increasing/decreasing film thicknesses d₁, d₃. In such a case, a film thickness d₂ was changed to approximate a transmittance and a phase difference of the phase shift film to a desired value.

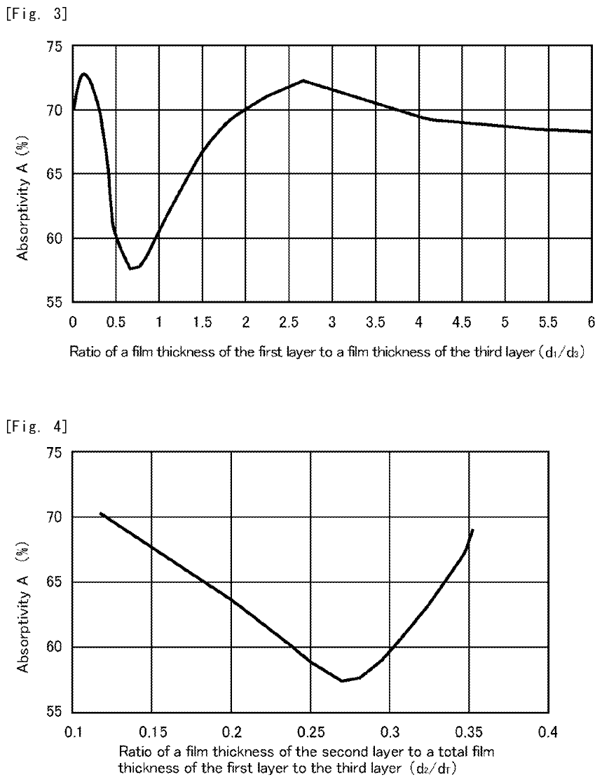

FIG. 3 is a graph showing a relation of a film thickness ratio d₁/d₃ of the first layer and the third layer and an absorptivity A of the phase shift film. The inventors of this application discovered that a relation of 0.5≤d₁/d₃<1 should be satisfied to achieve a phase shift film satisfying the three conditions of a predetermined phase difference (150 degrees or more and 210 degrees or less), 15% or more transmittance T, and 60% or less absorptivity A, as shown in the drawing.

Further, the inventors of this application focused on a relation of a film thickness ratio of a film thickness d₂ of a second layer and a total film thickness d_{T} of three layers including a first layer, a second layer, and a third layer (film thickness d₂/d_{T} which is a ratio of a film thickness d₂ of the second layer to a total film thickness d_{T} of the three layers) with an absorptivity A of a phase shift film. An optical simulation of the phase shift film was carried out, similar to the above mentioned in the explanation of FIG. 3. FIG. 4 is a graph showing a relation of an absorptivity A and a film thickness ratio d₂/d_{T} of a film thickness d₂ of a second layer and a total film thickness d_{T} of three layers including a first layer, a second layer, and a third layer of a phase shift film. The inventors of this application discovered that a relation of 0.24←₂/d_{T}≤0.3 should be satisfied to achieve a phase shift film simultaneously satisfying the three conditions of a predetermined phase difference (150 degrees or more and 210 degrees or less), 15% or more transmittance T, and 60% or less absorptivity A, as shown in the drawing. This disclosure has been made as a result of the diligent studies described above.

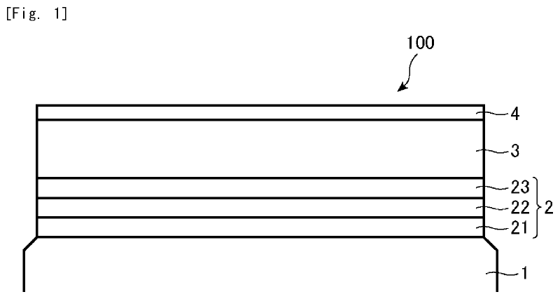

FIG. 1 is a cross-sectional view showing a configuration of a mask blank 100 of an embodiment of this disclosure. The mask blank 100 of this disclosure shown in FIG. 1 has a structure where a phase shift film 2, a light shielding film 3, and a hard mask film 4 are stacked in this order on a transparent substrate 1.

The transparent substrate 1 can be made of quartz glass, aluminosilicate glass, soda-lime glass, low thermal expansion glass (SiO₂—TiO₂ glass, etc.), etc., in addition to synthetic quartz glass. Among the above, synthetic quartz glass is particularly preferable as a material for forming the transparent substrate 1 of the mask blank for having a high transmittance to an ArF excimer laser light. A refractive index n of the material forming the transparent substrate 1 to an ArF exposure light wavelength (about 193 nm) is preferably 1.5 or more and 1.6 or less, more preferably 1.52 or more and 1.59 or less, and even more preferably 1.54 or more and 1.58 or less.

A transmittance T of the phase shift film 2 to an ArF exposure light is preferably 15% or more. Since the phase shift film 2 of the first embodiment has high design freedom, an adjustment is possible to increase a back surface reflectance R while satisfying the condition of phase difference of a predetermined range, even if a transmittance T is 15% or more. A transmittance T of the phase shift film 2 to an exposure light is preferably 16% or more, and more preferably 17% or more. On the other hand, as a transmittance T of the phase shift film 2 to an exposure light increases, it will be more difficult to increase a back surface reflectance R. Therefore, a transmittance T of the phase shift film 2 to an exposure light is preferably 40% or less, and more preferably 35% or less.

To obtain a proper phase shifting effect, it is desired for the phase shift film 2 to be adjusted such that a phase difference that generates between the transmitting ArF exposure light and the light that transmitted through the air for the same distance as a thickness of the phase shift film 2 is within the range of 150 degrees or more and 210 degrees or less. A phase difference of the phase shift film 2 is preferably 155 degrees or more, and more preferably 160 degrees or more. On the other hand, a phase difference of the phase shift film 2 is preferably 200 degrees or less, and more preferably 195 degrees or less.

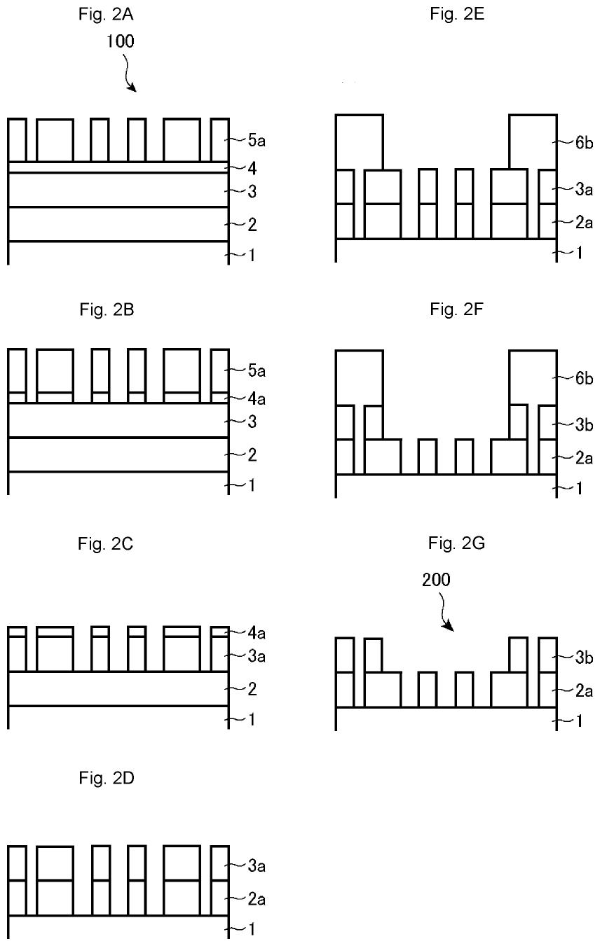

On the viewpoint of reducing a ratio of an ArF exposure light entered within the phase shift film 2 from being transformed into heat, the phase shift film 2 is desired to have a reflectance of the transparent substrate 1 side (back surface side) to an ArF exposure light (back surface reflectance) R of at least 20% or more in the state where only the phase shift film 2 exists on the transparent substrate 1 and the ArF exposure light entered into the transparent substrate is 100%. The state where only the phase shift film 2 exists on the transparent substrate 1 indicates a state where a light shielding pattern 3b is not stacked on a phase shift pattern 2a (region of phase shift pattern 2a where light shielding pattern 3b is not stacked) when a phase shift mask 200 (FIG. 2(g)) is manufactured from this mask blank 100. On the other hand, a back surface reflectance R being too high is not preferable in the state where only the phase shift film 2 exists, since greater influence will be imparted on an exposure transfer image by a reflected light of the back surface side of the phase shift film 2 when the phase shift mask 200 manufactured from this mask blank 100 was used to exposure-transfer an object to be transferred (resist film on semiconductor wafer, etc.). On this viewpoint, a back surface reflectance R of the phase shift film 2 to an ArF exposure light is preferably 40% or less.

The phase shift film 2 of this embodiment has a structure where a first layer 21, a second layer 22, and a third layer 23 are stacked from the transparent substrate 1 side. It is required to at least satisfy each condition of a transmittance T, a phase difference, and a back surface reflectance R given above in the entire phase shift film 2. To satisfy the above conditions, the phase shift film 2 of this embodiment is configured such that refractive indexes n₁, n₂, and n₃ of the first layer 21, the second layer 22, and the third layer 23, respectively, at a wavelength of an ArF exposure light satisfy relations of n₁>n₂ and n₂<n₃; extinction coefficients k₁, k₂, and k₃ of the first layer 21, the second layer 22, and the third layer 23, respectively, at a wavelength of an ArF exposure light satisfy relations of k₁>k₂ and k₂<k₃; and film thicknesses d₁, d₃ of the first layer 21 and the third layer 23, respectively, satisfy a relation of 0.5≤d₂/d₃<1. Further, the phase shift film 2 of this embodiment is configured such that a film thickness d₂ of the second layer 22 and a total film thickness d_{T} of the three layers including the first layer 21, the second layer 22, and the third layer 23 satisfy a relation of 0.24≤d₂/d_{T}≤0.3.

Considering the above, a refractive index n₁ of the first layer 21 is preferably 2.3 or more, and more preferably 2.4 or more. A refractive index n₁ of the first layer 21 is preferably 3.0 or less, and more preferably 2.8 or less. An extinction coefficient k₁ of the first layer 21 is preferably 0.2 or more, and more preferably 0.25 or more. Further, an extinction coefficient k₁ of the first layer 21 is preferably 0.5 or less, and more preferably 0.4 or less. A refractive index n₁ and an extinction coefficient k₁ of the first layer 21 are values derived by regarding the entire first layer 21 as a single, optically uniform layer.

A refractive index n₂ of the second layer 22 is preferably 1.7 or more, and more preferably 1.8 or more. Further, a refractive index n₂ of the second layer 22 is preferably less than 2.3, and more preferably 2.2 or less. An extinction coefficient k₂ of the second layer 22 is preferably 0.01 or more, and more preferably 0.02 or more. Further, an extinction coefficient k₂ of the second layer 22 is preferably 0.15 or less, and more preferably 0.13 or less. A refractive index n₂ and an extinction coefficient k₂ of the second layer 22 are values derived by regarding the entire second layer 22 as a single, optically uniform layer.

A refractive index n₃ of the third layer 23 is preferably 2.3 or more, and more preferably 2.4 or more. A refractive index n₃ of the third layer 23 is preferably 3.0 or less, and more preferably 2.8 or less. An extinction coefficient k₃ of the third layer 23 is preferably 0.2 or more, and more preferably 0.25 or more. An extinction coefficient k₃ of the third layer 23 is preferably 0.5 or less, and more preferably 0.4 or less. A refractive index n₃ and an extinction coefficient k₃ of the third layer 23 are values derived by regarding the entire third layer 23 as a single, optically uniform layer.

A refractive index n and an extinction coefficient k of a thin film including the phase shift film 2 are not determined only by the composition of the thin film. Film density and crystal condition of the thin film are also the factors that affect a refractive index n and an extinction coefficient k. Therefore, the conditions in forming a thin film by reactive sputtering are adjusted so that the thin film reaches desired refractive index n and extinction coefficient k. For allowing the first layer, the second layer, and the third layer to have a refractive index n and an extinction coefficient k of the above range, not only a ratio of mixed gas of noble gas and reactive gas (oxygen gas, nitrogen gas, etc.) is adjusted in forming a film by reactive sputtering, but various other adjustments are made upon forming a film by reactive sputtering, such as pressure in a film forming chamber, power applied to the sputtering target, and positional relationship such as distance between the target and the transparent substrate 1. Further, these film forming conditions are specific to film forming apparatuses, and are adjusted arbitrarily for the first layer 21, the second layer 22, and the third layer 23 to be formed to achieve desired refractive index n and extinction coefficient k.

The phase shift film 2 (first layer 21, second layer 22, third layer 23) is formed of a material containing a non-metallic element and silicon. A thin film formed of a material containing silicon and a transition metal tends to have a higher extinction coefficient k. To reduce the entire film thickness of the phase shift film 2, the phase shift film 2 can be formed of a material containing a non-metallic element, silicon, and a transition metal. The transition metal to be included in this case includes any one metal among molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), zinc (Zn), niobium (Nb), palladium (Pd), etc., or an alloy of these metals. On the other hand, the phase shift film 2 is preferably formed of a material consisting of a non-metallic element and silicon, or a material consisting of a metalloid element, a non-metallic element, and silicon. It is preferable not to include a transition metal when the phase shift film 2 requires high light fastness to an ArF exposure light. Further, in this case, it is preferable not to include metal elements excluding transition metals, since their possibility of causing reduction of light fastness to an ArF exposure light cannot be denied.

In the case of including a metalloid element in the phase shift film 2, it is preferable to include one or more metalloid elements selected from boron, germanium, antimony, and tellurium, since enhancement in conductivity of silicon to be used as a sputtering target can be expected.

In the case of including a non-metallic element in the phase shift film 2, it is preferable to include one or more non-metallic elements selected from nitrogen, carbon, fluorine, and hydrogen. These non-metallic elements include noble gas such as helium (He), argon (Ar), krypton (Kr), and xenon (Xe). Further, all of the first layer 21, the second layer 22, and the third layer 23 of the phase shift film 2 are preferably formed of a material containing nitrogen. Generally, compared to a thin film formed without nitrogen, a thin film formed of the same material as the thin film and including nitrogen tends to have a greater refractive index n. The higher a refractive index n of any of the first layer 21, the second layer 22, and the third layer 23 of the phase shift film 2, reduction can be made in the entire film thickness required to ensure a predetermined phase difference required on the phase shift film 2. Further, oxidation of pattern side wall is suppressed when a phase shift pattern is formed by including nitrogen in any of the first layer 21, the second layer 22, and the third layer 23 of the phase shift film 2.

The first layer 21 is preferably formed in contact with a surface of the transparent substrate 1. This is because a configuration where the first layer 21 contacts the surface of the transparent substrate 1 can obtain greater effect of enhancing a back surface reflectance R that is generated by the stacked structure of the first layer 21, the second layer 22, and the third layer 23 of the phase shift film 2. Incidentally, if only slight influence is given on the effect of enhancing the back surface reflectance R of the phase shift film 2, an etching stopper film can be provided between the transparent substrate 1 and the phase shift film 2.

A film thickness d₁ of the first layer 21 is preferably 30 nm or less, and more preferably 25 nm or less. Further, particularly considering enhancing a back surface reflectance R of the phase shift film 2, a film thickness d₁ of the first layer 21 is preferably 15 nm or more, and more preferably 17 nm or more.

It is preferable not to positively include oxygen in the first layer 21 (oxygen content through composition analysis of X-ray photoelectron spectroscopy, etc. is preferably 3 atom % or less, more preferably detection lower limit or less). This is because reduction of an extinction coefficient k₁ of the first layer 21 caused by including oxygen in the material forming the first layer is greater compared to other non-metallic elements, causing significant reduction of a back surface reflectance R of the phase shift film 2.

A refractive index n₁ of the first layer 21 is required to be greater than a refractive index n₂ of the second layer 22 (n₁>n₂), and an extinction coefficient k₁ of the first layer 21 to be greater than an extinction coefficient k₂ of the second layer 22 (k₂>k₂). Therefore, a nitrogen content of the material forming the first layer 21 is preferably 40 atom % or more, more preferably 45 atom % or more, and even more preferably 50 atom % or more. The nitrogen content of the material forming the first layer 21 is preferably 57 atom % or less. Including a nitrogen content more than a nitrogen content of a stoichiometrically stable Si₃N₄ (about 57 atom %) causes easier escaping of nitrogen from the first layer 21 through mask cleaning and heat generating in the first layer 21 during dry etching, etc. so that a nitrogen content tends to be reduced.

Unlike the first layer 21, the second layer 22 is preferably formed of a material containing oxygen. Further, the second layer is preferably formed of a material consisting of silicon, nitrogen, and oxygen, or a material consisting of silicon, nitrogen, oxygen, and one or more elements selected from a non-metallic element and a metalloid element. This is because the second layer 22 has the smallest refractive index n₂ and extinction coefficient k₂ among the three layers constructing the phase shift film 2, and a refractive index n₂ tends to decrease as an oxygen content of the material increases, and decreasing degree of an extinction coefficient k₂ tends to increase compared to nitrogen. An oxygen content of the material forming the second layer 22 is preferably 20 atom % or more, more preferably 25 atom % or more, and even more preferably 30 atom % or more. On the other hand, as an oxygen content of the second layer 22 increases, a total thickness d_{T} of the entire phase shift film 2 necessary to ensure predetermined transmittance T and phase difference to an ArF exposure light in the entire phase shift film 2 increases. Considering these points, an oxygen content of the material forming the second layer 22 is preferably 60 atom % or less, more preferably 55 atom % or less, and even more preferably 50 atom % or less.

Further, it is preferable for a nitrogen content of the material forming the second layer 22 to be less than a nitrogen content of the material forming the first layer 21 and the third layer 23. Therefore, a nitrogen content of the material forming the second layer 22 is preferably 5 atom % or more, and more preferably 10 atom % or more. Further, a nitrogen content of the material forming the second layer 22 is preferably 40 atom % or less, more preferably 35 atom % or less, and even more preferably 30 atom % or less.

As mentioned above, the second layer 22 has the smallest refractive index n₂ and extinction coefficient k₂ among the three layers forming the phase shift film 2. A film thickness d₂ of the second layer 22 being too thick causes an increase in a total film thickness d_{T} of the entire phase shift film 2. Thus, a film thickness d₂ of the second layer 22 is preferably 30 nm or less, more preferably 25 nm or less, and even more preferably 22 nm or less. If a film thickness d₂ of the second layer 23 is too thin, a reflection of an exposure light is reduced at an interface between the second layer 22 and the third layer 23, which may cause reduction in a back surface reflectance R of the phase shift film 2. Thus, a film thickness d₂ of the second layer 22 is preferably 10 nm or more, more preferably 15 nm or more, and even more preferably 16 nm or more.

It is preferable not to positively include oxygen in the third layer 23, similar as the first layer 21 (oxygen content through composition analysis of X-ray photoelectron spectroscopy, etc. is preferably 3 atom % or less, more preferably detection lower limit or less).

As mentioned above, a refractive index n₃ of the third layer 23 is required to be greater than a refractive index n₂ of the second layer 22 (n₂<n₃), and an extinction coefficient k₃ of the third layer 23 to be greater than an extinction coefficient k₂ of the second layer 22 (k₂<k₃). Therefore, a nitrogen content of the material forming the third layer 23 is preferably 40 atom % or more, more preferably 45 atom % or more, and even more preferably 50 atom % or more. The nitrogen content of the material forming the third layer 23 is preferably 57 atom % or less. Including a nitrogen content more than a nitrogen content of a stoichiometrically stable Si₃N₄ (about 57 atom %) causes easier escaping of nitrogen from the third layer 23 through mask cleaning and heat generating in the third layer 23 during dry etching, etc. so that a nitrogen content tends to be reduced.

Similar to the first layer 21, the third layer 23 has refractive index n₃ and extinction coefficient k₃ that are higher than the second layer 22. When a film thickness d₃ of the third layer 23 is too thick, it is necessary to reduce film thicknesses d₁, d₂ of the first layer 21 and the second layer 22 in order to achieve a predetermined transmittance T with the entire phase shift film 2, and thus, there is a risk that a back surface reflectance R of the phase shift film 2 is reduced. Thus, a film thickness d₃ of the third layer 23 is preferably 50 nm or less, more preferably 40 nm or less, and even more preferably 35 nm or less. Further, the third layer 23 has a refractive index n₃ and an extinction coefficient k₃ higher than those of the second layer 22, and a certain degree or more film thickness d₃ is required to increase a back surface reflectance R of the phase shift film 2. Thus, a film thickness d₃ of the third layer 23 is preferably 15 nm or more, and more preferably 25 nm or more.

As mentioned above, a film thickness ratio d₁/d₃ of the first layer 21 and the third layer 23 is preferably 0.5 or more, more preferably 0.52 or more, and even more preferably 0.55 or more. Further, a film thickness ratio d₁/d₃ of the first layer 21 and the third layer 23 is preferably less than 1, more preferably 0.99 or less, and even more preferably 0.95 or less.

Further, a film thickness ratio d₂/d_{T} of the second layer 22 and a total film thickness d_{T} of the three layers from the first layer 21 to the third layer 23 is preferably 0.24 or more, more preferably 0.245 or more, and even more preferably 0.25 or more. Further, a film thickness ratio d₂/d_{T} of the second layer 22 and a total film thickness d_{T} of the three layers from the first layer 21 to the third layer 23 is preferably 0.3 or less, more preferably 0.295 or less, and even more preferably 0.29 or less.

While the first layer 21, the second layer 22, and the third layer 23 of the phase shift film 2 are formed through sputtering, any sputtering including DC sputtering, RF sputtering, ion beam sputtering, etc. is applicable. Application of DC sputtering is preferable, considering the film forming rate. In the case where the target has low conductivity, while application of RF sputtering and ion beam sputtering is preferable, application of RF sputtering is more preferable considering the film forming rate.

While an explanation was made in this embodiment on the case of constructing the phase shift film 2 from three layers including the first layer 21, the second layer 22, and the third layer 23, a fourth layer can further be provided on the third layer 23, if only slightly affects the effect of enhancing a back surface reflectance R of the phase shift film 2. Although not particularly limited, the fourth layer is preferably formed of a material consisting of silicon and oxygen, or a material consisting of silicon, oxygen, and one or more elements selected from a non-metallic element and a metalloid element.

The mask blank 100 has a light shielding film 3 on the phase shift film 2. Generally, in a binary transfer mask, an outer peripheral region of a region where a transfer pattern is formed (transfer pattern forming region) is desired to ensure an optical density (OD) of a predetermined value or more to prevent the resist film from being subjected to an influence of an exposure light that transmitted through the outer peripheral region when an exposure-transfer was made on the resist film on a semiconductor wafer using an exposure apparatus. This point is similar in the case of a phase shift mask. Generally, the outer peripheral region of a transfer mask including a phase shift mask preferably has OD of 2.8 or more, and more preferably 3.0 or more. The phase shift film 2 has a function to transmit an exposure light at a predetermined transmittance T, and it is difficult to ensure an optical density of a predetermined value with the phase shift film 2 alone. Therefore, it is necessary to stack the light shielding film 3 on the phase shift film 2 at the stage of manufacturing the mask blank 100 to secure lacking optical density. With such a configuration of the mask blank 100, the phase shift mask 200 ensuring a predetermined value of optical density on the outer peripheral region can be manufactured by removing the light shielding film 3 of the region using the phase shifting effect (basically transfer pattern forming region) during manufacture of the phase shift mask 200 (see FIG. 2).

A single layer structure and a stacked structure of two or more layers are applicable to the light shielding film 3. Further, the light shielding film 3 of a single layer structure and each layer in the light shielding film 3 with a stacked structure of two or more layers may be configured by approximately the same composition in the thickness direction of the layer or the film, or with a composition gradient in the thickness direction of the layer.

The mask blank 100 of the embodiment shown in FIG. 1 is configured by stacking the light shielding film 3 on the phase shift film 2 without an intervening film. For the light shielding film 3 of this configuration, it is necessary to apply a material having a sufficient etching selectivity to etching gas used in forming a pattern in the phase shift film 2. The light shielding film 3 in this case is preferably formed of a material containing chromium. Materials containing chromium for forming the light shielding film 3 can include, in addition to chromium metal, a material containing chromium and one or more elements selected from oxygen, nitrogen, carbon, boron, and fluorine.

While a chromium-based material is generally etched by mixed gas of chlorine-based gas and oxygen gas, an etching rate of the chromium metal to the etching gas is not as high. Considering enhancing an etching rate of mixed gas of chlorine-based gas and oxygen gas to etching gas, the material forming the light shielding film 3 preferably contains chromium and one or more elements selected from oxygen, nitrogen, carbon, boron, and fluorine. Further, one or more elements among molybdenum, indium, and tin can be included in the material containing chromium for forming the light shielding film 3. Including one or more elements among molybdenum, indium, and tin can increase an etching rate to mixed gas of chlorine-based gas and oxygen gas.

The light shielding film 3 can be formed of a material containing a transition metal and silicon, if an etching selectivity to dry etching can be obtained between the material forming the third layer 23 (esp., surface layer portion). This is because a material containing a transition metal and silicon has high light shielding performance, which enables reduction of thickness of the light shielding film 3. The transition metal to be included in the light shielding film 3 includes one metal among molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), zinc (Zn), niobium (Nb), palladium (Pd), etc., or an alloy of these metals. Metal elements other than the transition metal elements to be included in the light shielding film 3 include aluminum (Al), indium (In), tin (Sn), gallium (Ga), etc.

Incidentally, the light shielding film 3 formed of two layers can have a structure where a layer consisting of a material containing chromium and a layer consisting of a material containing a transition metal and silicon are stacked, in this order, from the phase shift film 2 side. Concrete matters on the material containing chromium and the material containing a transition metal and silicon in this case are similar to the case of the light shielding film 3 described above.

It is preferable that the mask blank 100 in the state where the phase shift film 2 and the light shielding film 3 are stacked has 20% or more reflectance at the transparent substrate 1 side (back surface side) to an ArF exposure light (back surface reflectance). In the case where the light shielding film 3 is formed of a material containing chromium and in the case where the layer of the light shielding film 3 at the phase shift film 2 side is formed of a material containing chromium, chromium is photoexcited so that chromium is likely to move to the phase shift film 2 side when a large amount of ArF exposure light enters the light shielding film 3. This movement of chromium can be suppressed by making the back surface reflectance to an ArF exposure light 20% or more in the state where the phase shift film 2 and the light shielding film 3 are stacked. Further, in the case where the light shielding film 3 is formed of a material containing a transition metal and silicon, the transition metal is photoexcited so that the transition metal is likely to move to the phase shift film 2 side when a large amount of an ArF exposure light enters the light shielding film 3. The movement of the transition metal can be suppressed by setting the back surface reflectance to an ArF exposure light 20% or more in the state where the phase shift film 2 and the light shielding film 3 are stacked.

In the mask blank 100, a preferable configuration is that the light shielding film 3 has further stacked thereon a hard mask film 4 formed of a material having an etching selectivity to etching gas used in etching the light shielding film 3. Since the hard mask film 4 is basically not limited with regard to optical density, a thickness of the hard mask film 4 can be reduced significantly compared to a thickness of the light shielding film 3. Since a resist film of an organic material only requires a film thickness to function as an etching mask until dry etching for forming a pattern in the hard mask film 4 is completed, a thickness can be reduced significantly compared to conventional resist films. Reduction of film thickness of a resist film is effective for enhancing resist resolution and preventing collapse of pattern, which is extremely important in facing requirements for miniaturization.

In the case where the light shielding film 3 is formed of a material containing chromium, the hard mask film 4 is preferably formed of a material containing silicon. Since the hard mask film 4 in this case tends to have low adhesiveness with a resist film of an organic material, it is preferable to treat the surface of the hard mask film 4 with HMDS (Hexamethyldisilazane) to enhance surface adhesiveness. The hard mask film 4 in this case is more preferably formed of SiO₂, SiN, SiON, etc.

Further, in the case where the light shielding film 3 is formed of a material containing chromium, materials containing tantalum are also applicable as the materials of the hard mask film 4, in addition to the materials given above. The material containing tantalum in this case includes, in addition to tantalum metal, a material containing tantalum and one or more elements selected from nitrogen, oxygen, boron, and carbon, for example, Ta, TaN, TaO, TaON, TaBN, TaBO, TaBON, TaCN, TaCO, TaCON, TaBCN, and TaBOCN. Further, in the case where the light shielding film 3 is formed of a material containing silicon, the hard mask film 4 is preferably formed of the material containing chromium given above.

In the mask blank 100, a resist film formed of an organic-based material is preferably formed at a film thickness of 100 nm or less in contact with a surface of the hard mask film 4. In the case of a fine pattern to meet DRAM hp32 nm generation, a SRAF (Sub-Resolution Assist Feature) with 40 nm line width may be provided on a transfer pattern (phase shift pattern) to be formed in the hard mask film 4. However, even in this case, the cross-sectional aspect ratio of the resist pattern can be reduced to 1:2.5 so that collapse and peeling of the resist pattern can be prevented in developing and rinsing, etc. of the resist film. Incidentally, the resist film preferably has a film thickness of 80 nm or less.

FIG. 2 shows a phase shift mask 200 according to a first embodiment of this disclosure manufactured from the mask blank 100 of the above embodiment, and its manufacturing process. As shown in FIG. 2(g), the phase shift mask 200 is featured in that a phase shift pattern 2a as a transfer pattern is formed in a phase shift film 2 of the mask blank 100, and a light shielding pattern 3b is formed in a light shielding film 3. In the case of a configuration where a hard mask film 4 is provided on the mask blank 100, the hard mask film 4 is removed during manufacture of the phase shift mask 200.

The method of manufacturing the phase shift mask of the embodiment of this disclosure uses the mask blank 100 mentioned above, which is featured in including forming a transfer pattern in the light shielding film 3 by dry etching; forming a transfer pattern in the phase shift film 2 by dry etching with the light shielding film 3 including the transfer pattern as a mask; and forming a light shielding pattern 3b in the light shielding film 3 by dry etching with a resist film (resist pattern 6b) including a light shielding pattern as a mask. The method of manufacturing the phase shift mask 200 of this disclosure is explained below according to the manufacturing steps shown in FIG. 2. Explained herein is the method of manufacturing the phase shift mask 200 using the mask blank 100 having the hard mask film 4 stacked on the light shielding film 3. Further, a material containing chromium is applied to the light shielding film 3, and a material containing silicon is applied to the hard mask film 4 in this case.

First, a resist film is formed in contact with the hard mask film 4 of the mask blank 100 by spin coating. Next, a first pattern, which is a transfer pattern (phase shift pattern) to be formed in the phase shift film 2, was exposed and written with an electron beam on the resist film, and a predetermined treatment such as developing was conducted, to thereby form a first resist pattern 5a having a phase shift pattern (see FIG. 2(a)). Subsequently, dry etching was conducted using fluorine-based gas with the first resist pattern 5a as a mask, and a first pattern (hard mask pattern 4a) was formed in the hard mask film 4 (see FIG. 2(b)).

Next, after removing the first resist pattern 5a, dry etching was conducted using mixed gas of chlorine-based gas and oxygen gas with the hard mask pattern 4a as a mask, and a first pattern (light shielding pattern 3a) is formed in the light shielding film 3 (see FIG. 2(c)). Subsequently, dry etching was conducted using fluorine-based gas with the light shielding pattern 3a as a mask, and a first pattern (phase shift pattern 2a) was formed in the phase shift film 2, and in the meanwhile, the hard mask pattern 4a was removed (see FIG. 2(d)).

Next, a resist film was formed on the mask blank 100 by spin coating. Next, a second pattern, which is a pattern (light shielding pattern) to be formed in the light shielding film 3, was exposed and written with an electron beam in the resist film, and a predetermined treatment such as developing was conducted, to thereby form a second resist pattern 6b having a light shielding pattern (see FIG. 2(e)). Subsequently, dry etching was conducted using mixed gas of chlorine-based gas and oxygen gas with the second resist pattern 6b as a mask, and a second pattern (light shielding pattern 3b including light shielding band) was formed in the light shielding film 3 (see FIG. 2(f)). Further, the second resist pattern 6b was removed, predetermined treatments such as cleaning were carried out, and the phase shift mask 200 was obtained (see FIG. 2(g)).

There is no particular limitation on chlorine-based gas to be used for the dry etching described above, as long as Cl is included. The chlorine-based gas includes, for example, Cl₂, SiCl₂, CHCl₃, CH₂Cl₂, CCl₄, and BCl₃. Further, there is no particular limitation on fluorine-based gas to be used for the dry etching described above, as long as F is included. The fluorine-based gas includes, for example, CHF₃, CF₄, C₂F₆, C₄F₈, and SF₆. Particularly, fluorine-based gas free of C can further reduce damage on a glass substrate for having a relatively low etching rate to a glass substrate.

The phase shift mask 200 of this disclosure is manufactured using the mask blank 100 mentioned above. Therefore, the phase shift film 2 having a transfer pattern formed therein (phase shift pattern 2a) has a transmittance T of 15% or more to an ArF exposure light, and a phase difference between an exposure light transmitted through the phase shift pattern 2a and the exposure light that transmitted through the air for the same distance as a thickness of the phase shift pattern 2a of within the range of 150 degrees or more and 210 degrees or less, and in addition, an absorptivity A of an ArF exposure light is 60% or less. This phase shift mask 200 has 20% or more back surface reflectance R in a region of the phase shift pattern 2a where the light shielding pattern 3b is not stacked (region on transparent substrate 1 where only phase shift pattern 2a exists). This can reduce the amount of an ArF exposure light entering inside of the phase shift film 2, and can reduce the amount of light that transforms into heat within the phase shift film 2 by emitting an ArF exposure light from the phase shift film 2 at an amount of light corresponding to the predetermined transmittance.

The phase shift mask 200 preferably has 40% or less back surface reflectance R at a region of the phase shift pattern 2a where the light shielding pattern 3b is not stacked. This is for the purpose of preventing application of great influence on an exposure transfer image by reflected light of the back surface side of the phase shift pattern 2a when the phase shift mask 200 was used to exposure-transfer an object to be transferred (resist film on a semiconductor wafer, etc.).

The phase shift mask 200 preferably has 20% or more back surface reflectance at a region on the transparent substrate 1 of the phase shift pattern 2a where the light shielding pattern 3b is stacked. In the case where the light shielding pattern 3a is formed of a material containing chromium or in the case where the layer at the phase shift pattern 2a side of the light shielding pattern 3a is formed of a material containing chromium, movement of chromium in the light shielding pattern 3a into the phase shift pattern 2a can be suppressed. Further, in the case where the light shielding pattern 3a is formed of a material containing a transition metal and silicon, movement of the transition metal in the light shielding pattern 3a into the phase shift pattern 2a can be suppressed.

The method of manufacturing the semiconductor device of this disclosure is featured in using the phase shift mask 200 given above and subjecting a resist film on a semiconductor substrate to exposure transfer of the transfer pattern. The phase shift pattern 2a of the phase shift mask 200 has a high back surface reflectance to an ArF exposure light, and an amount of an ArF exposure light entering into the phase shift pattern 2a is reduced. Due to the above, a ratio of an ArF exposure light entering within the phase shift pattern 2a to be transformed into heat is reduced, and sufficiently suppresses the heat causing thermal expansion of the transparent substrate 1 to displace the position of the phase shift pattern 2a. Therefore, even if the phase shift mask 200 was set on an exposure apparatus, and the step of irradiating an ArF exposure light from the transparent substrate 1 side of the phase shift mask 200 and exposure-transferring to an object to be transferred (resist film on semiconductor wafer etc.) was continuously performed, position precision of the phase shift pattern 2a is high so that a desired pattern can be transferred continuously to the object to be transferred at a high precision.

### Example 1

The embodiment of this disclosure is described in greater detail below together with examples.

### Example 1

### [Manufacture of Mask Blank]

A transparent substrate 1 formed of a synthetic quartz glass with a size of a main surface of about 152 mm×about 152 mm and a thickness of about 6.35 mm was prepared. End surfaces and the main surface of the transparent substrate 1 were polished to a predetermined surface roughness, and thereafter subjected to predetermined cleaning treatment and drying treatment. The optical properties of the transparent substrate 1 were measured, and a refractive index n was 1.556 and an extinction coefficient k was 0.00 at the wavelength of an ArF exposure light.

Next, a first layer 21 of a phase shift film 2 consisting of silicon and nitrogen (Si₃N₄ film Si:N=43 atom %:57 atom %) was formed in contact with a surface of the transparent substrate 1 at a film thickness d₁ of 18.9 nm. The first layer 21 was formed by placing the transparent substrate 1 in a single-wafer RF sputtering apparatus, and by RF sputtering using a silicon (Si) target, with mixed gas of krypton (Kr) and nitrogen (N₂) as sputtering gas. Next, a second layer 22 of the phase shift film 2 consisting of silicon, nitrogen, and oxygen (SiON film Si:O:N=40 atom %:38 atom %:22 atom %) was formed on the first layer 21 at a film thickness d₂ of 17.6 nm. The second layer 22 was formed by reactive sputtering (RF sputtering) using a silicon (Si) target, with mixed gas of argon (Ar), oxygen (O₂), and nitrogen (N₂) as sputtering gas. Next, a third layer 23 of the phase shift film 2 consisting of silicon and nitrogen (Si₃N₄ film Si:N=43 atom %:57 atom %) was formed on the second layer 22 at a film thickness d₃ of 33.0 nm. The third layer 23 was formed by reactive sputtering (RF sputtering) using a silicon (Si) target, with mixed gas of krypton (Kr) and nitrogen (N₂) as sputtering gas. Namely, a total film thickness d_{T} of the three layers including the first layer 21, the second layer 22, and the third layer 23 of the phase shift film 2 of Example 1 is 69.5 nm.

The composition of the first layer 21, the second layer 22, and the third layer 23 is the result obtained from measurement by X-ray photoelectron spectroscopy (XPS). The same applies to other films hereafter.

Next, the transparent substrate 1 having the phase shift film 2 formed was subjected to heat treatment for reducing film stress of the phase shift film 2. A transmittance T and a phase difference of the phase shift film to a light of 193 nm wavelength were measured using a phase shift measurement apparatus (MPM193 manufactured by Lasertec), and a transmittance T was 20.7% and a phase difference was 177.0 degrees. Moreover, each optical property was measured for the first layer 21, the second layer 22, and the third layer 23 of the phase shift film 2, and the first layer 21 had a refractive index n₁ of 2.61 and an extinction coefficient k₁ of 0.36; the second layer 22 had a refractive index n₂ of 1.90 and an extinction coefficient k₂ of 0.035; and the third layer 23 had a refractive index n₃ of 2.61 and an extinction coefficient k₃ of 0.36. A film thickness ratio d₁/d₃ of the first layer 21 and the third layer 23 in Example 1 was 0.573. Further, a film thickness ratio d₂/d_{T} of a film thickness d₂ of the second layer 22 and a total film thickness d_{T} of the three layers from the first layer 21 to the third layer 23 in Example 1 was 0.253. A back surface reflectance (reflectance at transparent substrate 1 side) R of the phase shift film 2 to a light of 193 nm wavelength was 20.8%, and an absorptivity A of an ArF exposure light was 58.5%.

Thus, the phase shift film 2 of Example 1 is configured such that refractive indexes n₁, n₂, and n₃ of the first layer 21, the second layer 22, and the third layer 23, respectively, satisfy relations of n₁>n₂ and n₂<n₃; extinction coefficients k₁, k₂, and k₃ of the first layer 21, the second layer 22, and the third layer 23, respectively, satisfy relations of k₁>k₂ and k₂<k₃; and film thicknesses d₁, d₃ of the first layer 21 and the third layer 23, respectively, satisfy a relation of 0.5≤d₁/d₃<1. Further, a film thickness d₂ of the second layer 22 and a total film thickness d_{T} of the three layers including the first layer 21, the second layer 22, and the third layer 23 satisfy a relation of 0.24≤d₂/d_{T}≤0.3. The phase shift film 2 of Example 1 has optical properties of a predetermined phase difference (150 degrees or more and 210 degrees or less) and 15% or more transmittance that are enough to obtain a sufficient phase shifting effect, and satisfies an absorptivity A of 60% or less.

Next, the transparent substrate 1 having the phase shift film 2 formed thereon was placed in a single-wafer DC sputtering apparatus, and by reactive sputtering (DC sputtering) using a chromium (Cr) target with mixed gas of argon (Ar), carbon dioxide (CO₂), and helium (He) as sputtering gas, a light shielding film 3 consisting of CrOC (CrOC film: Cr:O:C=56 atom %:27 atom %:17 atom %) was formed on the phase shift film 2 at a thickness of 56 nm. The optical density (OD) to a light of 193 nm wavelength in the stacked structure of the phase shift film 2 and the light shielding film 3 was 3.0 or more. Further, another transparent substrate 1 was prepared, only a light shielding film 3 was formed under the same film-forming conditions, the optical properties of the light shielding film 3 were measured, and a refractive index n was 1.95 and an extinction coefficient k was 1.42.

Next, the transparent substrate 1 with the phase shift film 2 and the light shielding film 3 stacked thereon was placed in a single-wafer RF sputtering apparatus, and by RF sputtering using a silicon dioxide (SiO₂) target with argon (Ar) gas as sputtering gas, a hard mask film 4 consisting of silicon and oxygen was formed on the light shielding film 3 at a thickness of 12 nm. Through the above procedure, the mask blank 100 was formed, having a structure where the phase shift film 2 of a three layer structure, the light shielding film 3, and the hard mask film 4 are stacked on the transparent substrate 1.

### [Manufacture of Phase Shift Mask]

Next, a phase shift mask 200 of Example 1 was manufactured through the following procedure using the mask blank 100 of Example 1. First, a surface of the hard mask film 4 was subjected to HMDS treatment. Subsequently, a resist film of a chemically amplified resist for electron beam writing was formed in contact with a surface of the hard mask film 4 by spin coating at a film thickness of 80 nm. Next, a first pattern, which is a phase shift pattern to be formed in the phase shift film 2, was written by an electron beam in the resist film, predetermined cleaning and developing treatments were conducted, and a first resist pattern 5a having the first pattern was formed (see FIG. 2(a)).

Next, dry etching using CF₄ gas was conducted with the first resist pattern 5a as a mask, and a first pattern (hard mask pattern 4a) was formed in the hard mask film 4 (see FIG. 2(b)). Thereafter the first resist pattern 5a was removed.

Subsequently, dry etching was conducted using mixed gas of chlorine and oxygen (gas flow ratio Cl₂:O₂=10:1) with the hard mask pattern 4a as a mask, and a first pattern (light shielding pattern 3a) was formed in the light shielding film 3 (see FIG. 2(c)). Next, dry etching was conducted using fluorine-based gas (SF₆+He) with the light shielding pattern 3a as a mask, and a first pattern (phase shift pattern 2a) was formed in the phase shift film 2, and in the meanwhile, the hard mask pattern 4a was removed (see FIG. 2(d)).

Next, a resist film of a chemically amplified resist for electron beam writing was formed on the light shielding pattern 3a by spin coating at a film thickness of 150 nm. Next, a second pattern, which is a pattern (light shielding pattern) to be formed in the light shielding film, was exposed and written in the resist film, further subjected to predetermined treatments such as developing, and a second resist pattern 6b having the light shielding pattern was formed (FIG. 2(e)). Subsequently, dry etching was conducted using mixed gas of chlorine and oxygen (gas flow ratio Cl₂:O₂=4:1) with the second resist pattern 6b as a mask, and a second pattern (light shielding pattern 3b) was formed in the light shielding film 3 (FIG. 2(f)). Further, the second resist pattern 6b was removed, predetermined treatments such as cleaning were carried out, and the phase shift mask 200 was obtained (see FIG. 2(g)).

The manufactured half tone phase shift mask 200 of Example 1 was set on a mask stage of an exposure apparatus using an ArF excimer laser as an exposure light, an ArF exposure light was irradiated from the transparent substrate 1 side of the phase shift mask 200, and the pattern was exposure-transferred in a resist film on a semiconductor device. The resist film after the exposure transfer was subjected to predetermined treatments to form a resist pattern, and the resist pattern was observed using an SEM (Scanning Electron Microscope). As a result, the amount of in-plane position displacement from the design pattern was within a tolerable range. From the above result, it can be considered that a circuit pattern can be formed at high precision on a semiconductor device with the resist pattern as a mask.

### Example 2

### [Manufacture of Mask Blank]

A mask blank 100 of Example 2 was manufactured through the same procedure as Example 1, except for the phase shift film 2. The change in the phase shift film 2 of Example 2 compared to the phase shift film 2 of Example 1 is film thicknesses d₁, d₂, and d₃ of the first layer 21, the second layer 22, and the third layer 23, respectively. Concretely, the first layer 21 of 24.4 nm film thickness d₁, the second layer 22 of 21.4 nm film thickness d₂, and the third layer 23 of 27 nm film thickness d₃ of the phase shift film 2 were formed in contact with a surface of the transparent substrate 1 through the same procedure as Example 1. Namely, a total film thickness d_{T} of the first layer 21, the second layer 22, and the third layer 23 of the phase shift film 2 of Example 2 is 72.8 nm.

Further, the phase shift film 2 of Example 2 was also subjected to heat treatment under the same treatment conditions as Example 1. A transmittance and a phase difference of the phase shift film 2 to a light of 193 nm wavelength were measured using a phase shift measurement apparatus (MPM193 manufactured by Lasertec), and a transmittance was 20.7% and a phase difference was 177.2 degrees. Further, each optical properties (refractive index and extinction coefficient) were measured for the first layer 21, the second layer 22, and the third layer 23 of the phase shift film 2, which were identical to those of Example 1. A film thickness ratio d₁/d₃ of the first layer 21 and the third layer 23 of Example 2 was 0.904. Further, a film thickness ratio d₂/d_{T} of a film thickness d₂ of the second layer 22 and a total film thickness d_{T} of the three layers from the first layer 21 to the third layer 23 in Example 2 was 0.294. A back surface reflectance (reflectance at the transparent substrate 1 side) R of the phase shift film 2 to a light of 193 nm wavelength was 20.3%, and an absorptivity of an ArF exposure light was 59.0%.

Thus, the phase shift film 2 of Example 2 is configured such that refractive indexes n₁, n₂, and n₃ of the first layer 21, the second layer 22, and the third layer 23, respectively, satisfy relations of n₁>n₂ and n₂<n₃; extinction coefficients k₁, k₂, and k₃ of the first layer 21, the second layer 22, and the third layer 23, respectively, satisfy relations of k₁>k₂ and k₂<k₃; and film thicknesses d₁, d₃ of the first layer 21 and the third layer 23, respectively, satisfy a relation of 0.5≤d₁/d₃<1. Further, a film thickness d₂ of the second layer 22 and a total film thickness d_{T} of the three layers including the first layer 21, the second layer 22, and the third layer 23 satisfy a relation of 0.24≤d₂/d_{T}≤0.3. The phase shift film 2 of Example 2 has optical properties of a predetermined phase difference (150 degrees or more and 210 degrees or less) and 15% or more transmittance that are enough to obtain a sufficient phase shifting effect, and satisfies an absorptivity A of 60% or less.

Through the same procedure as Example 1, a light shielding film 3 and a hard mask film 4 were formed on the phase shift film 2, and a mask blank 100 of Example 2 was manufactured. The optical density (OD) to light of 193 nm wavelength of the stacked structure of the phase shift film 2 and the light shielding film 3 was 3.0 or more.

### [Manufacture of Phase Shift Mask]

Next, a phase shift mask 200 of Example 2 was manufactured through the same procedure as Example 1 using the mask blank 100 of Example 2.

The manufactured half tone phase shift mask 200 of Example 2 was set on a mask stage of an exposure apparatus using an ArF excimer laser as an exposure light, an ArF exposure light was irradiated from the transparent substrate 1 side of the phase shift mask 200, and the pattern was exposure-transferred in a resist film on a semiconductor device. The resist film after the exposure transfer was subjected to predetermined treatments to form a resist pattern, and the resist pattern was observed using an SEM (Scanning Electron Microscope). As a result, the amount of in-plane position displacement from the design pattern was within a tolerable range. From the above result, it can be considered that a circuit pattern can be formed at high precision on a semiconductor device with the resist pattern as a mask.

### Comparative Example 1

### [Manufacture of Mask Blank]

A mask blank of Comparative Example 1 was manufactured through the same procedure as Example 1, except for a phase shift film. The change in the phase shift film of Comparative Example 1 compared to the phase shift film 2 of Example 1 is film thicknesses d₁, d₂, and d₃ of the first layer, the second layer, and the third layer, respectively. Concretely, the first layer of 32 nm film thickness d₁, the second layer of 25.4 nm film thickness d₂, and the third layer of 15 nm film thickness d₃ of the phase shift film were formed in contact with a surface of the transparent substrate through the same procedure as Example 1. Namely, a total film thickness d_{T} of the first layer, the second layer, and the third layer of the phase shift film of Comparative Example 1 is 72.4 nm.

Further, the phase shift film of Comparative Example 1 was subjected to heat treatment under the same treatment conditions as Example 1. A transmittance and a phase difference of the phase shift film to a light of 193 nm wavelength were measured using a phase shift measurement apparatus (MPM193 manufactured by Lasertec), and a transmittance was 20.7% and a phase difference was 176.9 degrees. Further, each optical properties (refractive index and extinction coefficient) were measured for the first layer, the second layer, and the third layer of the phase shift film, which were identical to those of Example 1. A film thickness ratio d₁/d₃ of the first layer and the third layer in Comparative Example was 2.133. Further, a film thickness ratio d₂/d_{T} of a film thickness d₂ of the second layer and a total film thickness d_{T} of the three layers from the first layer to the third layer in Comparative Example 1 was 0.351. A back surface reflectance (reflectance at transparent substrate side) R of the phase shift film to a light of 193 nm wavelength was 8.7%, and an absorptivity of an ArF exposure light was 70.6%.

Thus, the phase shift film of Comparative Example 1 is configured such that refractive indexes n₁, n₂, and n₃ of the first layer, the second layer, and the third layer, respectively, satisfy relations of n₁>n₂ and n₂<n₃; and extinction coefficients k₁, k₂, and k₃ of the first layer, the second layer, and the third layer, respectively, satisfy relations of k₁>k₂ and k₂<k₃. However, film thicknesses d₁ and d₃ of the first layer and the third layer, respectively, do not satisfy a relation of 0.5≤d₁/d₃<1. Further, a film thickness d₂ of the second layer and a total film thickness d_{T} of the three layers including the first layer, the second layer, and the third layer do not satisfy a relation of 0.24≤d₂/d_{T}≤0.3. Although the phase shift film of Comparative Example 1 has optical properties of a predetermined phase difference (150 degrees or more and 210 degrees or less) and 15% or more transmittance that are enough to obtain a sufficient phase shifting effect, an absorptivity A of 60% or less is not satisfied.

Through the above procedures, a mask blank of Comparative Example 1 having a structure where a phase shift film, a light shielding film, and a hard mask film are stacked on the transparent substrate was manufactured. The optical density (OD) to a light of 193 nm wavelength in the stacked structure of the phase shift film and the light shielding film was 3.0 or more.

### [Manufacture of Phase Shift Mask]

Next, using the mask blank of Comparative Example 1, a phase shift mask of Comparative Example 1 was manufactured through the same procedure as Example 1.

The manufactured half tone phase shift mask of Comparative Example 1 was set on a mask stage of an exposure apparatus using an ArF excimer laser as an exposure light, an ArF exposure light was irradiated from the transparent substrate side of the phase shift mask, and the pattern was exposure-transferred in a resist film on a semiconductor device. The resist film after the exposure transfer was subjected to predetermined treatments to form a resist pattern, and the resist pattern was observed using an SEM (Scanning Electron Microscope). As a result, the amount of position displacement from the design pattern was significant, and several portions out of tolerable range were found. From this result, generation of short-circuit or disconnection is expected on a circuit pattern to be formed in the semiconductor device using the resist pattern as a mask.

### DESCRIPTION OF REFERENCE NUMERALS

1. transparent substrate
2. phase shift film
21. first layer
22. second layer
23. third layer
2a. phase shift pattern
3. light shielding film
3a,3b light shielding pattern
4. hard mask film
4a. hard mask pattern
5a. first resist pattern
6b. second resist pattern
100. mask blank
200. phase shift mask

1. A mask blank comprising a phase shift film on a transparent substrate,
wherein a transmittance of the phase shift film with respect to an exposure light of an ArF excimer laser is 15% or more, and
wherein the phase shift film is configured to transmit the exposure light so that transmitted light has a phase difference of 150 degrees or more and 210 degrees or less with respect to the exposure light transmitted through the air for a same distance as a thickness of the phase shift film,
wherein the phase shift film contains a non-metallic element and silicon,
wherein the phase shift film has a structure where a first layer, a second layer, and a third layer are stacked in this order from a side of the transparent substrate,
wherein refractive indexes n₁, n₂, and n₃ of the first layer, the second layer, and the third layer, respectively, at a wavelength of the exposure light satisfy relations of n₁>n₂ and n₂<n₃,
wherein extinction coefficients k₁, k₂, and k₃ of the first layer, the second layer, and the third layer, respectively, at a wavelength of the exposure light satisfy relations of k₁>k₂ and k₂<k₃, and
wherein film thicknesses d₁ and d₃ of the first layer and the third layer, respectively, satisfy a relation of 0.5≤d₁/d₃≤1.

2. The mask blank according to claim 1, wherein a film thickness d₂ of the second layer and a total film thickness d_{T} of three layers comprising the first layer, the second layer, and the third layer satisfy a relation of 0.24≤d₂/d_{T}≤0.3.

3. The mask blank according to claim 1, wherein the refractive index n₁ of the first layer is 2.3 or more, and the extinction coefficient k₁ of the first layer is 0.2 or more.

4. The mask blank according to claim 1, wherein the refractive index n₂ of the second layer is 1.7 or more, and the extinction coefficient k₂ of the second layer is 0.01 or more.

5. The mask blank according to claim 1, wherein the refractive index n₃ of the third layer is 2.3 or more, and the extinction coefficient k₃ of the third layer is 0.2 or more.

6. The mask blank according to claim 1, wherein the phase shift film consists of a non-metallic element and silicon, or consists of a metalloid element, a non-metallic element, and silicon.

7. The mask blank according to claim 1, wherein the first layer, the second layer, and the third layer all contain nitrogen.

8. The mask blank according to claim 1, wherein the second layer contains oxygen.

9. The mask blank according to claim 1 comprising a light shielding film on the phase shift film.

10. A phase shift mask comprising a phase shift film having a transfer pattern on a transparent substrate,
wherein a transmittance of the phase shift film with respect to an exposure light of an ArF excimer laser is 15% or more, and
wherein the phase shift film is configured to transmit the exposure light so that transmitted light has a phase difference of 150 degrees or more and 210 degrees or less with respect to the exposure light transmitted through the air for a same distance as a thickness of the phase shift film,
wherein the phase shift film is contains a non-metallic element and silicon,
wherein the phase shift film has a structure where a first layer, a second layer, and a third layer are stacked in this order from a side of the transparent substrate,
wherein refractive indexes n₁, n₂, and n₃ of the first layer, the second layer, and the third layer, respectively, at a wavelength of the exposure light satisfy relations of n₁>n₂ and n₂<n₃,
wherein extinction coefficients k₁, k₂, and k₃ of the first layer, the second layer, and the third layer, respectively, at a wavelength of the exposure light satisfy relations of k₁>k₂ and k₂<k₃, and
wherein film thicknesses d₁ and d₃ of the first layer and the third layer, respectively, satisfy a relation of 0.5≤d₁/d₃<1.

11. The phase shift mask according to claim 10, wherein a film thickness d₂ of the second layer and a total film thickness d_{T} of three layers comprising the first layer, the second layer, and the third layer satisfy a relation of 0.24≤d₂/d_{T}≤0.3.

12. The phase shift mask according to claim 10, wherein the refractive index n₁ of the first layer is 2.3 or more and the extinction coefficient k₁ of 0.2 or more.

13. The phase shift mask according to claim 10, wherein the refractive index n₂ of the second layer is 1.7 or more, and the extinction coefficient k₂ of the second layer is 0.01 or more.

14. The phase shift mask according to claim 10, wherein the refractive index n₃ of the third layer is 2.3 or more, and the extinction coefficient k₃ of the third layer is 0.2 or more.

15. The phase shift mask according to claim 10, wherein the phase shift film consists of a non-metallic element and silicon, or consists of a metalloid element, a non-metallic element, and silicon.

16. The phase shift mask according to claim 10, wherein the first layer, the second layer, and the third layer all contain nitrogen.

17. The phase shift mask according to claim 10, wherein the second layer contains oxygen.

18. The phase shift mask according to claim 10 comprising a light shielding film having a pattern comprising a light shielding band on the phase shift film.

19. (canceled)

20. A method of manufacturing a semiconductor device comprising the step of using the phase shift mask according to claim 18 and subjecting a resist film on a semiconductor substrate to exposure transfer of the transfer pattern.
